(19) United States
(12) Patent Application Publication
(10) Pub. No.: US 2024/0224702 A1
(43) Pub. Date: Jul. 4, 2024

(54) DISPLAY DEVICE

(71) Applicant: LG Display Co., Ltd., Seoul (KR)

(72) Inventors: JONGHYUN KIM, Paju-si (KR); SEONG-IL KIM, Seoul (KR); YOUNGMIN OH, Yeosu-si (KR)

(73) Assignee: LG Display Co., Ltd., Seoul (KR)

(21) Appl. No.: 18/239,520

(22) Filed: Aug. 29, 2023

(30) Foreign Application Priority Data
Dec. 30, 2022 (KR) 10-2022-0191305

(51) Int. Cl. H10K 59/50; H10K 59/126

(52) U.S. Cl. CPC H10K 59/50; H10K 59/126

(57) ABSTRACT

A display device can include a light emitting portion positioned in a display area and including a light emitting element, a transparent portion positioned in the display area, and a switching portion positioned on the light emitting portion and the transparent portion. The switching portion includes a first transparent electrode, a liquid crystal layer positioned on the first transparent electrode, and a second transparent electrode positioned on the liquid crystal layer. The display device is capable of achieving excellent light efficiency in a mirror mode while being capable of switching between a transparent mode and the mirror mode.

### CROSS-REFERENCE TO RELATED APPLICATION

This application claims priority from Korean Patent Application No. 10-2022-0191305, filed in the Republic of Korea on Dec. 30, 2022, the entire contents of which are hereby expressly incorporated by reference into the present application.

### BACKGROUND

### Field

Embodiments of the disclosure relate to display devices.

### Description of Related Art

Display devices that display various pieces of information on the screen are part of a key technology in the era of information and communication technology, and play a role to deliver a variety of information to users.

As technology develops, the display device can perform not only the function of displaying information on the screen but also other functions. When the display device displays information and is transparent (transparent mode) or has reflectivity (mirror mode) like a mirror, the display device can be used as conventional display devices.

In particular, if the display device is able to freely switch between the transparent mode and the mirror mode, the display device can be advantageously used for more diverse purposes.

Some display devices can implement only either the transparent mode or mirror mode and, although implemented with the mirror mode, its light efficiency can deteriorate.

### SUMMARY OF THE DISCLOSURE

Thus, the inventors of the disclosure have invented a display device capable of achieving excellent light efficiency in a mirror mode while being capable of switching between a transparent mode and the mirror mode, which addresses the limitations and disadvantages associated with the related art.

Embodiments of the disclosure can provide a display device capable of achieving excellent light efficiency in a mirror mode while being capable of switching between the transparent mode and the mirror mode by including a light emission portion, a transparent portion, and a switching portion including a liquid crystal layer.

Embodiments of the disclosure can provide a display device comprising a light emitting portion, a transparent portion, and a switching portion.

According to an aspect of the disclosure, the light emitting portion can be positioned in a display area. The light emitting portion can include a light emitting element. The transparent portion can be positioned in the display area.

The switching portion can be positioned on the light emitting portion and the transparent portion. The switching portion can include a first transparent electrode, a liquid crystal layer positioned on the first transparent electrode, and a second transparent electrode positioned on the liquid crystal layer.

According to embodiments of the disclosure, there can be provided a display device capable of achieving excellent light efficiency in the mirror mode while being capable of switching between the transparent mode and the mirror mode by including a switching portion including a light emission portion, a transparent portion, and a liquid crystal layer.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is a cross-sectional view of a display device and a circuit diagram of a subpixel according to embodiments of the disclosure;

FIGS. 3 and 4 are cross-sectional views illustrating operation states of a display device according to embodiments of the disclosure;

FIGS. 5, 6, 7, 8, and 9 are cross-sectional views illustrating operation states of a display device in various modes according to embodiments of the disclosure;

FIGS. 10 and 11 are cross-sectional views illustrating a display device according to embodiments of the disclosure;

FIG. 12 is a plan view illustrating a display device according to embodiments of the disclosure;

FIGS. 13 and 14 are cross-sectional views illustrating a display device according to embodiments of the disclosure; and

FIGS. 15 and 16 are plan views illustrating a display device according to embodiments of the disclosure.

### DETAILED DESCRIPTION OF THE EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings. All the components of each display device according to all embodiments of the disclosure are operatively coupled and configured. Further, one or more features from each figure and/or embodiment can be applied to another figure and/or embodiment of the disclosure. Additionally, the description of the same elements (e.g., used by the same reference numerals) may be briefly provided or may be omitted below.

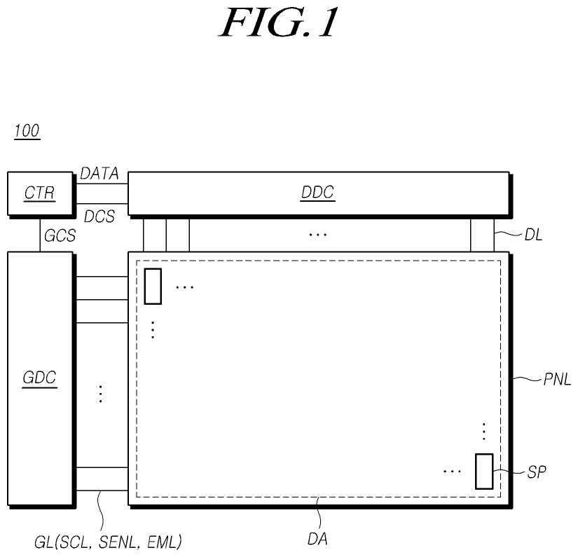

FIG. 1 is a view illustrating a system configuration of an organic light emitting display device 100 according to embodiments of the disclosure.

Referring to FIG. 1, an organic light emitting display device 100 according to the present embodiments can include a display panel PNL where a plurality of data lines DL and a plurality of gate lines GL are arranged and a plurality of subpixels SP connected with the plurality of data lines DL and the plurality of gate lines GL are arranged in an active area or display area DA. The display device further includes a driving circuit for driving the display panel PNL.

From a functional point of view, the driving circuit can include a data driving circuit DDC driving the plurality of data lines DL, a gate driving circuit GDC driving the plurality of gate lines GL, and a controller CTR controlling the data driving circuit DDC and the gate driving circuit GDC.

In the display panel PNL, the plurality of data lines DL and the plurality of gate lines GL can be disposed to cross each other. For example, the plurality of data lines DL can be arranged in rows or columns, and the plurality of gate lines GL can be arranged in columns or rows. For ease of description, it is assumed below that the plurality of data lines DL are arranged in rows, and the plurality of gate lines GL are arranged in columns.

The controller CTR supplies various control signals DCS and GCS necessary for the driving operations of the data driving circuit DDC and the gate driving circuit GDC to control the data driving circuit DDC and the gate driving circuit GDC.

The controller CTR starts scanning according to a timing implemented in each frame, converts input image data input from the outside into image data DATA suited for the data signal format used in the data driving circuit DDC, outputs the image data DATA, and controls data driving at an appropriate time suited for scanning.

The controller CTR can be a timing controller used in typical display technology, or a control device that can perform other control functions as well as the functions of the timing controller.

The controller CTR can be implemented as a separate component from the data driving circuit DDC, or the controller CTR, along with the data driving circuit DDC, can be implemented as an integrated circuit.

The data driving circuit DDC receives the image data DATA from the controller CTR and supply data voltage to the plurality of data lines DL, thereby driving the plurality of data lines DL. Here, data driving circuit DDC is also referred to as a ‘source driving circuit.’

The data driving circuit DDC can include at least one source driver integrated circuit S-DIC. Each source driver integrated circuit S-DIC can include a shift register, a latch circuit, a digital-to-analog converter DAC, and an output buffer. In some cases, each source driver integrated circuit S-DIC can further include an analog-digital converter ADC.

Each source driver integrated circuit S-DIC can be connected to the bonding pad of the display panel PNL in a tape automated bonding (TAB) or chip-on-glass (COG) scheme or can be directly disposed on the display panel PNL or, in some cases, can be integrated in the display panel PNL. Each source driver integrated circuit S-DIC can also be implemented in a chip-on-film (COF) scheme to be mounted on a source-circuit film connected to the display panel PNL.

The gate driving circuit GDC sequentially drives the plurality of gate lines GL by sequentially supplying scan signals to the plurality of gate lines GL. Here, gate driving circuit GDC is also referred to as a ‘scan driving circuit.’

The gate driving circuit GDC can be connected to the bonding pad of the display panel PNL in a tape automated bonding (TAB) or chip-on-glass (COG) scheme or can be implemented in a gate-in-panel (GIP) type to be directly disposed on the display panel PNL or, in some cases, can be integrated in the display panel PNL. Further, the gate driving circuit GDC can be implemented in a chip-on-film (COF) scheme implemented with a plurality of gate driver integrated circuits G-DIC and mounted on a gate-circuit film connected to the display panel PNL.

The gate driving circuit GDC sequentially supplies scan signals of On voltage or Off voltage to the plurality of gate lines GL under the control of the controller CTR.

When a specific gate line is opened by the gate driving circuit GDC, the data driving circuit DDC converts the image data DATA received from the controller CTR into an analog data voltage and supplies the analog data voltage to the plurality of data lines DL.

The data driving circuit DDC can be positioned on only one side (e.g., the top or bottom side) of the display panel PNL and, in some cases, the data driver DDR can be positioned on each of two opposite sides (e.g., both the top and bottom sides) of the display panel PNL depending on, e.g., driving schemes or panel designs.

The gate driving circuit GDC can be positioned on only one side (e.g., the left or right side) of the display panel PNL and, in some cases, the gate driving circuit GDR can be positioned on each of two opposite sides (e.g., both the left and right sides) of the display panel PNL depending on, e.g., driving schemes or panel designs.

The plurality of gate lines GL disposed on the display panel PNL can include a plurality of scan lines SCL, a plurality of sense lines SENL, and a plurality of emission control lines EML. The scan line SCL, sense line SENL, and emission control line EML are lines for transferring different types of gate signals (scan signals, sense signals, and emission control signals) to the gate nodes of different types of transistors (scan transistors, sense transistors, and emission control transistors).

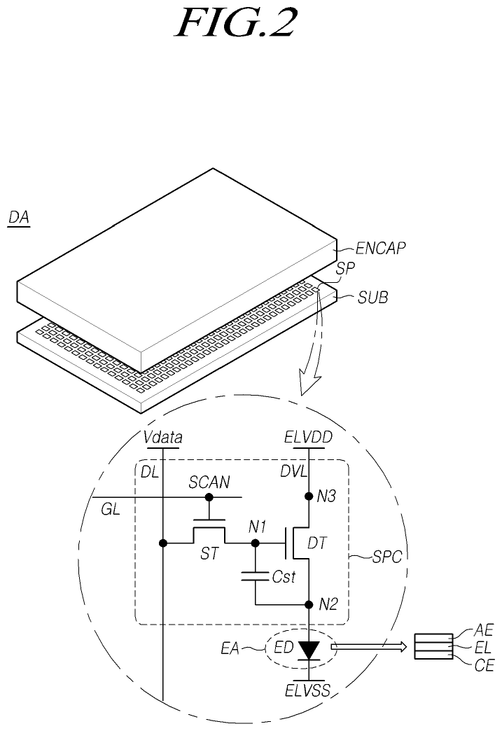

FIG. 2 illustrates a schematic cross-sectional structure of a display device and a circuit diagram of a subpixel according to embodiments of the disclosure.

Referring to FIG. 2, a plurality of subpixels SP can be disposed in the display area DA. The plurality of subpixels SP can be disposed in the normal area NA and the first optical area OA1 and the second optical area OA2 included in the display area DA.

Referring to FIG. 2, each of the plurality of subpixels SP can include a light emitting element ED and a subpixel circuit unit SPC configured to drive the light emitting element ED.

Referring to FIG. 2, the subpixel circuit unit SPC can include a driving transistor DT for driving the light emitting element ED, a scan transistor ST for transferring the data voltage Vdata to the first node N1 of the driving transistor DT, and a storage capacitor Cst for maintaining a constant voltage during one frame.

The driving transistor DT can include the first node N1 to which the data voltage can be applied, a second node N2 electrically connected with the light emitting element ED, and a third node N3 to which a driving voltage ELVDD is applied from a driving voltage line DVL. The first node N1 in the driving transistor DT can be a gate node, the second node N2 can be a source node or a drain node, and the third node N3 can be the drain node or the source node. For convenience of description, described below is an example in which the first node N1 in the driving transistor DT is a gate node, the second node N2 is a source node, and the third node N3 is a drain node.

The light emitting element ED can include an anode electrode AE, a light emitting layer EL, and a cathode electrode CE. The anode electrode AE can be a pixel electrode disposed in each subpixel SP and be electrically connected to the second node N2 of the driving transistor DT of each subpixel SP. The cathode electrode CE can be a common electrode commonly disposed in the plurality of subpixels SP, and a base voltage ELVSS can be applied thereto.

For example, the anode electrode AE can be a pixel electrode, and the cathode electrode CE can be a common electrode. Conversely, the anode electrode AE can be a common electrode, and the cathode electrode CE can be a pixel electrode. Hereinafter, for convenience of description, it is assumed that the anode electrode AE is a pixel electrode and the cathode electrode CE is a common electrode.

The light emitting element ED can have a predetermined emission area EA. The emission area EA of the light emitting element ED can be defined as an area where the anode electrode AE, the light emitting layer EL, and the cathode electrode CE overlap.

For example, the light emitting element ED can be an organic light emitting diode (OLED), an inorganic light emitting diode, or a quantum dot light emitting element. When the light emitting element ED is an organic light emitting diode, the light emitting layer EL of the light emitting element ED can include an organic light emitting layer EL including an organic material.

The scan transistor ST can be on/off controlled by a scan signal SCAN, which is a gate signal, applied via the gate line GL and be electrically connected between the first node N1 of the driving transistor DT and the data line DL.

The storage capacitor Cst can be electrically connected between the first node N1 and second node N2 of the driving transistor DT.

The subpixel circuit unit SPC can have a 2T (transistor) 1C (capacitor) structure which includes two transistors DT and ST and one capacitor Cst as shown in FIG. 2 and, in some cases, each subpixel SP can further include one or more transistors or one or more capacitors.

The capacitor Cst can be an external capacitor intentionally designed to be outside the driving transistor DT, but not a parasite capacitor (e.g., Cgs or Cgd) which is an internal capacitor that can be present between the first node N1 and the second node N2 of the driving transistor DT. Each of the driving transistor DT and the scan transistor ST can be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer ENCAP can be disposed to prevent penetration of external moisture or oxygen into the circuit elements (particularly, the light emitting element ED). The encapsulation layer ENCAP can be disposed to cover the light emitting elements ED.

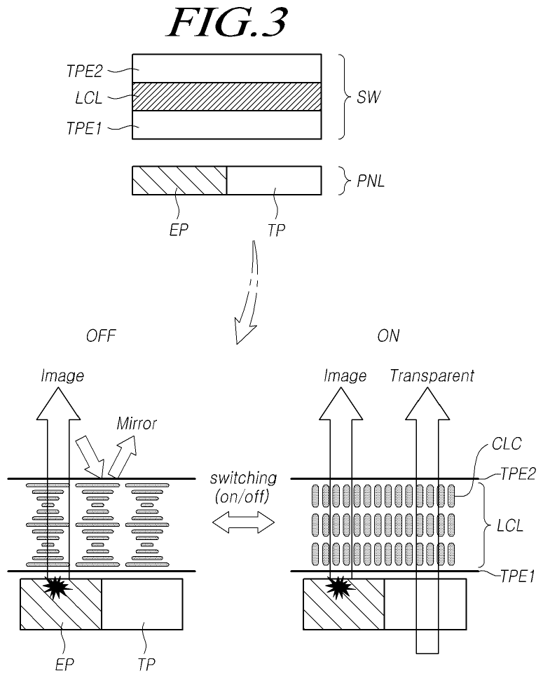

FIG. 3 is a cross-sectional view illustrating an operation state of a display device according to embodiments of the disclosure.

Referring to FIG. 3, the display device can include a light emitting portion EP, a transparent portion TP, and a switching portion SW.

The light emitting portion EP and the transparent portion TP can be part of an area constituting the display panel PNL. The light emitting portion EP and the transparent portion TP can be positioned in the display area.

The light emitting portion EP can include a light emitting element. Since the light emitting element is positioned in the light emitting portion EP, light can be emitted from the light emitting portion EP so that the display device can display information.

The transparent portion TP can be a transparent portion in the display area. As the transparent portion TP is positioned in the display area, the display device can operate in the transparent mode.

The switching portion SW can be positioned on the light emitting portion EP and the transparent portion TP. The switching portion SW can be positioned on the display panel PNL including the light emitting portion EP and the transparent portion TP. As the switching portion SW is positioned on the light emitting portion EP and the transparent portion TP, and the switching portion SW is turned on or off by an electrical signal, the display device can be switched to the transparent mode or the mirror mode.

The switching portion SW can include a first transparent electrode TPE1, a liquid crystal layer LCL positioned on the first transparent electrode TPE1, and a second transparent electrode TPE2 positioned on the liquid crystal layer LCL. As the switching portion SW includes the transparent electrodes TPE1 and TPE2 and the liquid crystal layer LCL, light can be passed through the switching portion SW or be reflected by the switching portion SW.

The liquid crystal layer LCL can include a cholesteric liquid crystal CLC.

The cholesteric liquid crystal CLC can be vertically oriented when a voltage is applied to the first transparent electrode TPE1 and the second transparent electrode TPE2. Here, vertical can mean a direction perpendicular to the display area of the display device. Further, that the voltage is applied to the first transparent electrode TPE1 and the second transparent electrode TPE2 can mean that an electric field is formed between the first transparent electrode TPE1 and the second transparent electrode TPE2.

The cholesteric liquid crystal CLC can be cholesterically oriented when no voltage is applied to the first transparent electrode TEP1 and the second transparent electrode TPE2. Here, that no voltage is applied to the first transparent electrode TPE1 and the second transparent electrode TPE2 can mean that no electric field is formed between the first transparent electrode TPE1 and the second transparent electrode TPE2.

As the switching portion SW includes the transparent electrodes TPE1 and TPE2 and the liquid crystal layer LCL described above, the switching portion SW can pass the light generated by the light emitting portion EP in the on state in which the electric field is formed by the transparent electrodes TPE1 and TPE2, and allow the light passing through the transparent portion TP to pass through the switching portion SW. Further, the switching portion SW can allow the external light to be reflected while passing the light generated by the light emitting portion EP in an off state in which no electric field is formed by the transparent electrodes TPE1 and TPE2.

The first transparent electrode TPE1 and the second transparent electrode TPE2 can be positioned in the entire display area. In other words, the first transparent electrode TPE1 and the second transparent electrode TPE2 can be formed to be entirely deposited on the entire display area.

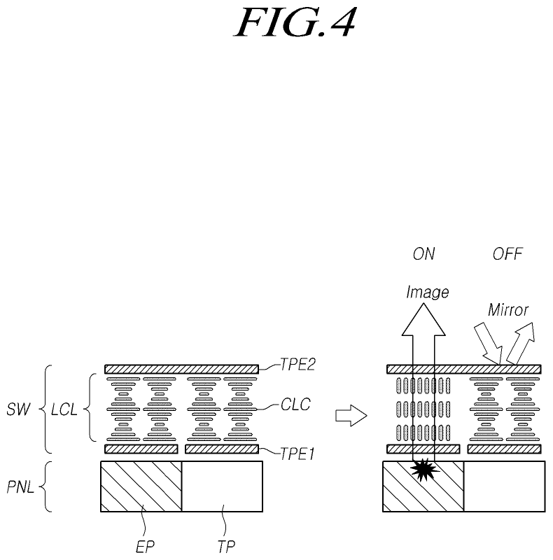

FIG. 4 is a cross-sectional view illustrating operation states of a display device according to embodiments of the disclosure. Unless otherwise described, the matters regarding the display device illustrated in FIG. 4 can be the same as the corresponding matters of the display device described above with reference to FIG. 3. In such case, the description of at least some of the same elements is omitted below for the sake of brevity or is briefly provided.

Referring to FIG. 4, the first transparent electrode TPE1 can be patterned to correspond to the light emitting portion EP and the transparent portion TP. In other words, the first transparent electrode TPE1 can include a portion corresponding to the light emitting portion EP and a portion corresponding to the transparent portion TP, and these two portions can be electrically connected to different power sources without being electrically connected to each other. In a case where the first transparent electrode TPE1 is included, when an electric field is applied to the liquid crystal layer LCL included in the switching portion SW, an electric field can be independently applied to a portion corresponding to the light emitting portion EP and a portion corresponding to the transparent portion TP. For example, an electric field can be applied to a portion of the liquid crystal layer LCL corresponding to the light emitting portion EP, and an electric field may not be applied to a portion of the liquid crystal layer LCL corresponding to the transparent portion. In a portion corresponding to the light emitting portion EP to which an electric field is applied, the cholesteric liquid crystal CLC can be vertically oriented to pass the light generated by the light emitting portion EP, and in a portion corresponding to the transparent portion TP to which no electric field is applied, the cholesteric liquid crystal CLC can be cholesterically oriented to reflect external light.

As described above, the display device according to embodiments of the disclosure can switch to various operation modes by including the light emitting portion EP, the transparent portion TP, and the switching portion SW.

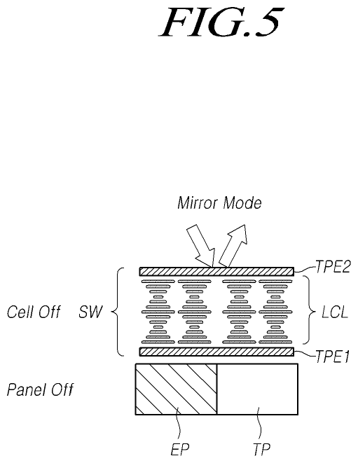

FIGS. 5 to 9 are cross-sectional schematically views illustrating a display device according to embodiments of the disclosure. More specifically, FIG. 5 is a view illustrating that a display device according to embodiments of the disclosure operates in a mirror mode.

Referring to FIG. 5, if the display panel portion is turned off not to generate light, and the cell included in the switching portion SW is turned off, the liquid crystal included in the liquid crystal layer LCL can reflect external light. Accordingly, since the display device is identified as a mirror when viewed as a whole, the display device can operate in the mirror mode.

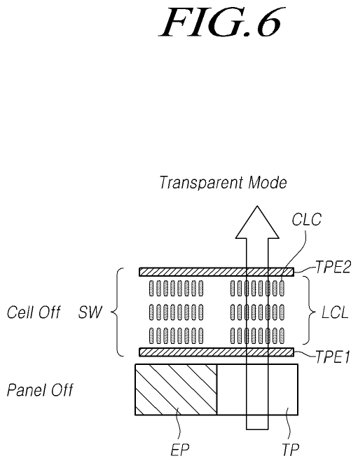

FIG. 6 is a view illustrating that a display device operates in a transparent display mode according to embodiments of the disclosure.

Referring to FIG. 6, the display panel portion can be turned on to generate light, and the cell included in the switching portion SW can be turned on to allow the liquid crystal included in the liquid crystal layer LCL to pass light. Accordingly, when viewed as a whole, the display device can operate in a transparent display mode in which information is displayed in the display area while the display device is transparent.

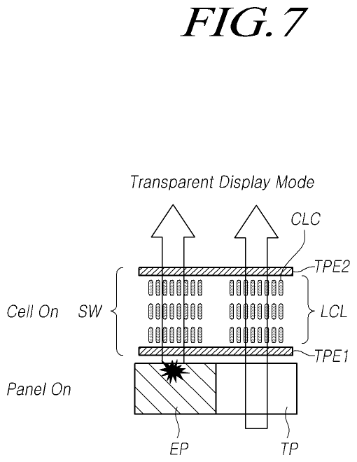

FIG. 7 is a view illustrating that a display device operates in a transparent mode according to embodiments of the disclosure.

Referring to FIG. 7, the display panel portion can be turned off not to generate light, and the cell included in the switching portion SW can be turned on to allow the liquid crystal included in the liquid crystal layer LCL to pass light. Accordingly, when viewed as a whole, the display device can be recognized as transparent and operate in the transparent mode.

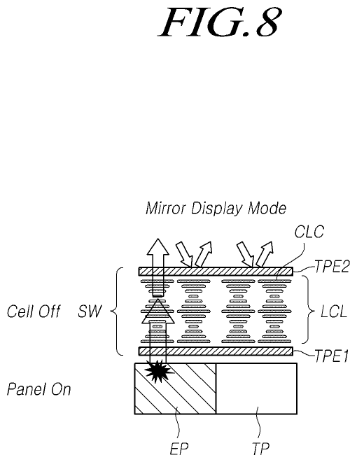

FIG. 8 is a view illustrating that a display device operates in a mirror display mode according to embodiments of the disclosure.

Referring to FIG. 8, the display panel portion can be turned on to generate light, and the cell included in the switching portion SW can be turned off so that the liquid crystal included in the liquid crystal layer LCL can reflect external light. Accordingly, when viewed as a whole, the display device can be recognized as an information-displayed mirror and operate in the mirror display mode.

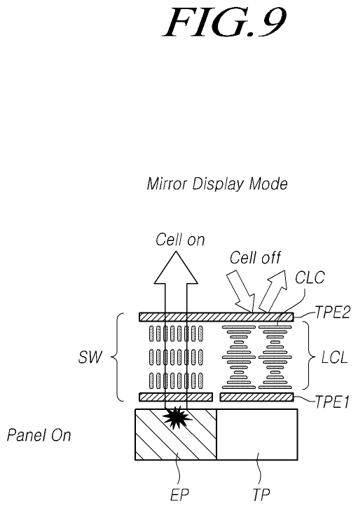

FIG. 9 is a view illustrating that a display device operates in a mirror display mode according to embodiments of the disclosure. In the display device according to the embodiments illustrated in FIG. 9, unlike the display devices illustrated in FIGS. 5 to 8, the first transparent electrode TPE1 can be patterned to correspond to the light emitting portion EP and the transparent portion TP. When the patterned first transparent electrode TPE1 is included, all of the operation modes illustrated in FIGS. 5 to 8 can be implemented, and the mirror display mode described in connection with FIG. 8 can be implemented with better efficiency.

Referring to FIG. 9, a display panel portion can be turned on to generate light, and cells included in the switching portion SW can be split driven. More specifically, the cells of the portion corresponding to the light emitting portion EP can be turned on to allow light generated by the light emitting portion EP to pass through the switching portion SW better, and the cells of the portion corresponding to the transparent portion TP can be turned off to reflect external light. In the display device illustrated in FIG. 8, the light generated by the light emitting portion EP can be somewhat absorbed by the cholesterically oriented liquid crystal layer LCL. However, in FIG. 9, the light generated by the light emitting portion EP can pass through the switching portion SW while being prevented from luminance deterioration through split driving of the cells included in the switching portion SW.

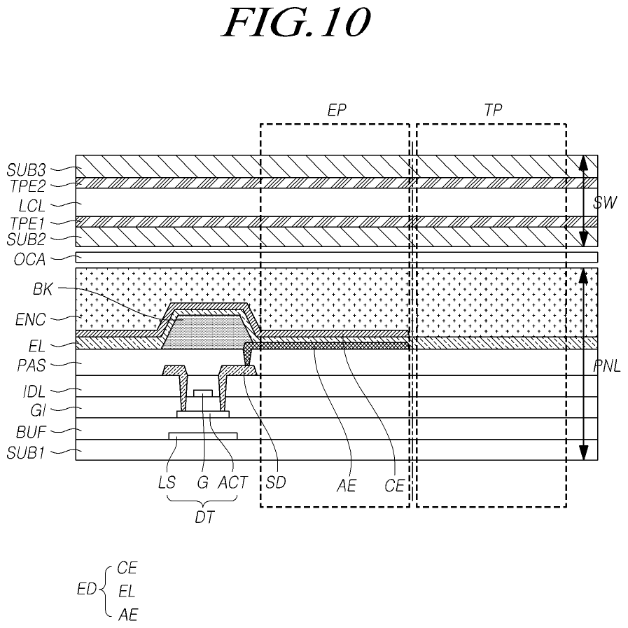

FIG. 10 is a cross-sectional view of a display device according to embodiments of the disclosure.

Referring to FIG. 10, a light emitting element ED can include an anode electrode AE, a light emitting layer EL positioned on the anode electrode AE, and a cathode electrode CE positioned on the light emitting layer EL.

The anode electrode AE and the cathode electrode CE may not be positioned on the transparent portion EP. In other words, the anode electrode AE and the cathode electrode CE are positioned without overlapping the transparent portion EP. As the anode electrode AE and the cathode electrode CE are not positioned on the transparent portion EP, the transparent portion EP can have a higher light transmittance.

The light emitting layer EL can be positioned on the transparent portion EP. In this example, the light emitting layer EL can be positioned in the entire display area of the display device. In other words, the light emitting layer EL can be formed by an entire surface deposition method. Since the light emitting layer EL has excellent light transmittance, even if the light emitting layer EL is also positioned on the transparent portion EP, the transparent portion EP can have high light transmittance, and since entire surface deposition is performed without performing a separate patterning process when generating the light emitting layer EL, the display device can be manufactured by an easier process.

The display device can further include a driving transistor DT. The driving transistor DT can be positioned not to overlap the transparent portion TP.

The display device can further include a light shield LS positioned under the driving transistor DT. The light shield LS can be positioned to overlap the driving transistor DT. The light shield LS can be positioned not to overlap the transparent portion TP. As the light shield LS is positioned not to overlap the transparent portion TP, the transparent portion TP can have a higher light transmittance.

The display device can include a first substrate SUB1 on which the light emitting element ED is positioned. The first substrate SUB1 can be a substrate on which various insulation films BUF, GI, IDL, PAS, and BK are positioned, and on which various circuit elements such as the transistor DT and various metal layers are positioned.

The display device can include a second substrate SUB2 on which the liquid crystal layer LCL is positioned. The display device can include an adhesive layer OCA positioned between the first substrate SUB1 and the second substrate SUB2. In other words, the display device can have a structure in which the cell constituting the display panel PNL and the cell constituting the switching portion SW are bonded to each other by the adhesive layer OCA.

The display device can include a third substrate SUB3 positioned on the second transparent electrode TPE2.

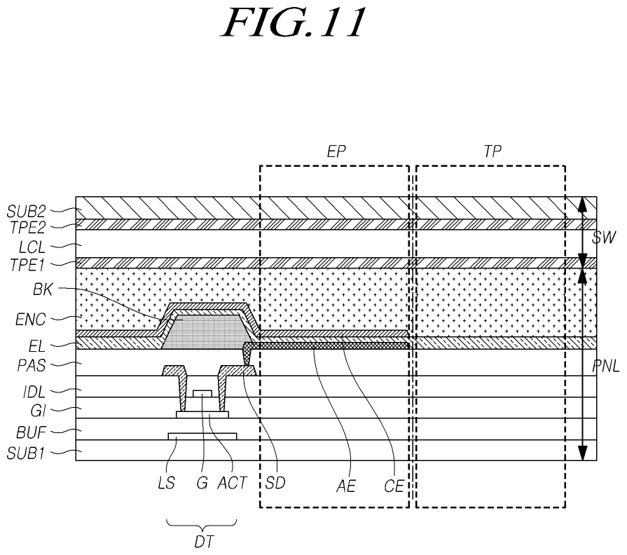

FIG. 11 is a cross-sectional view of a display device according to embodiments of the disclosure. Unless otherwise described, the matters regarding the display device illustrated in FIG. 11 can be the same as (or have the same or similar elements as) the matters for the display device described above with reference to FIG. 10. In such case, the description of at least some of the same elements is omitted below for the sake of brevity or is briefly provided.

Referring to FIG. 11, unlike the display device illustrated in FIG. 10, the display device here may not include a separate adhesive layer between the switching portion SW and the display panel PNL. In other words, as illustrated in FIG. 11, the display device can have a single cell structure including a switching portion SW and a display panel PNL.

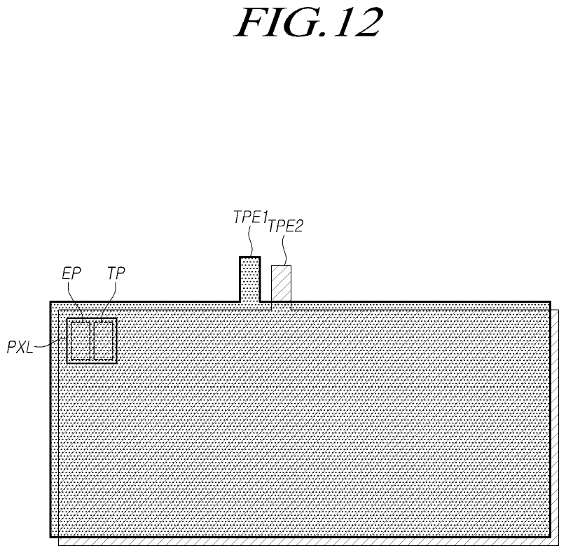

FIG. 12 is a plan view illustrating a display device according to embodiments of the disclosure. More specifically, FIG. 12 is a plan view of the display device illustrated in FIGS. 10 and 11.

Referring to FIG. 12, the first transparent electrode TPE1 and the second transparent electrode TPE2 can be positioned in the entire area of the display area in which the pixel PXL is positioned. The pixel PXL can include a light emitting portion EP and a transparent portion TP.

The first transparent electrode TPE1 can be electrically connected to a first power source, and the second transparent electrode TPE2 can be electrically connected to a second power source. In other words, different voltages can be applied to the first transparent electrode TPE1 and the second transparent electrode TPE2 to form an electric field between the first transparent electrode TPE1 and the second transparent electrode TPE2.

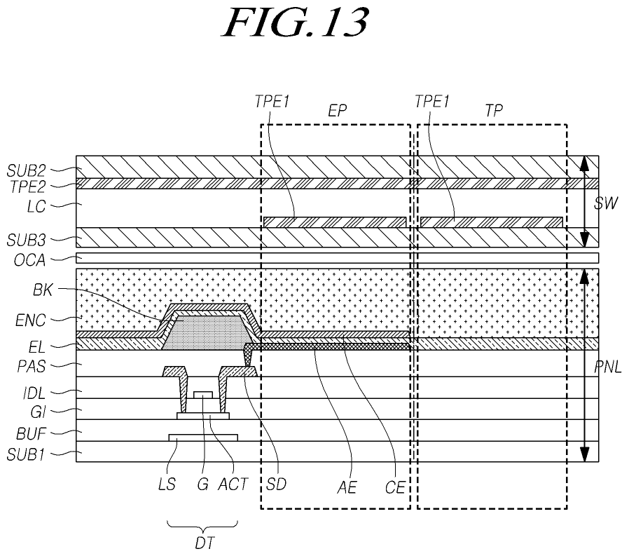

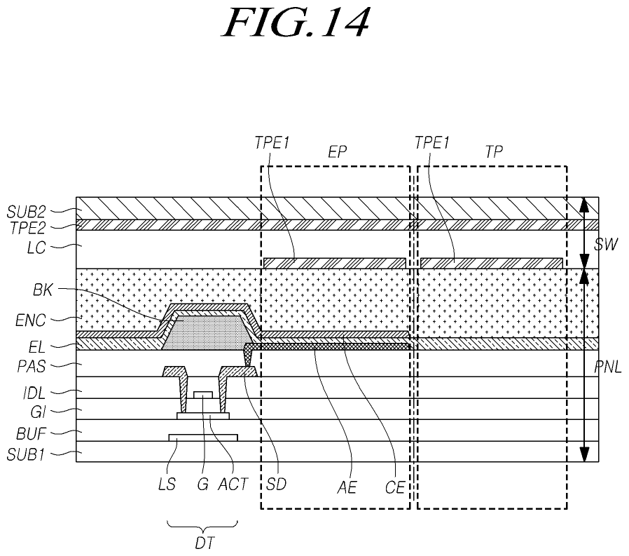

FIGS. 13 and 14 are plan views illustrating a display device according to embodiments of the disclosure. Unless otherwise described, the matters regarding the display device illustrated in FIGS. 13 and 14 can be the same as (or have the same or similar elements as) the matters for the display device described above with reference to FIGS. 10 and 11. In such case, the description of at least some of the same elements is omitted below for the sake of brevity or is briefly provided.

Referring to FIGS. 13 and 14, the first transparent electrode TPE1 can include a portion corresponding to the light emitting portion EP and a portion corresponding to the transparent portion TP. When the first transparent electrode TPE includes a portion corresponding to the light emitting portion EP and a portion corresponding to the transparent portion TP, the switching portion SW described above with reference to FIGS. 4 and 9 can be split driven, so that the display device can be more precisely operated.

In the first transparent electrode TPE1, the portion corresponding to the light emitting portion EP and the portion corresponding to the transparent portion TP can be positioned to be spaced apart from each other. When the portion of the first transparent electrode TPE1 (that corresponds to the light emitting portion EP) and the portion of the first transparent electrode TPE1 (that corresponds to the transparent portion TP) are positioned to be spaced apart from each other (e.g., separated from each other), the switching portion SW can be split driven (e.g., selectively or independently driven).

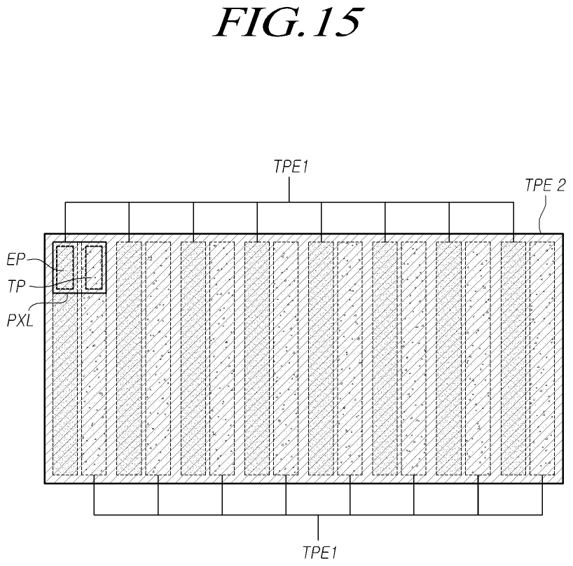

FIG. 15 is a plan view illustrating a display device according to embodiments of the disclosure. More specifically, FIG. 15 can be a plan view of the display device according to the embodiments illustrated in FIGS. 13 and 14.

Referring to FIG. 15, a portion corresponding to the light emitting portion EP can be electrically connected to a first power source, a portion corresponding to the transparent portion TP can be electrically connected to a second power source, and the second transparent electrode TPE2 can all be positioned in the entire display area and can be electrically connected to a third power source. If the portion corresponding to the light emitting portion EP is electrically connected to the first power source, the portion corresponding to the transparent portion TP is electrically connected to the second power source, and the second transparent electrode TPE2 is positioned in the entire display area and electrically connected to the third power source, the switching portion SW can be split driven (e.g., selectively or independently driven).

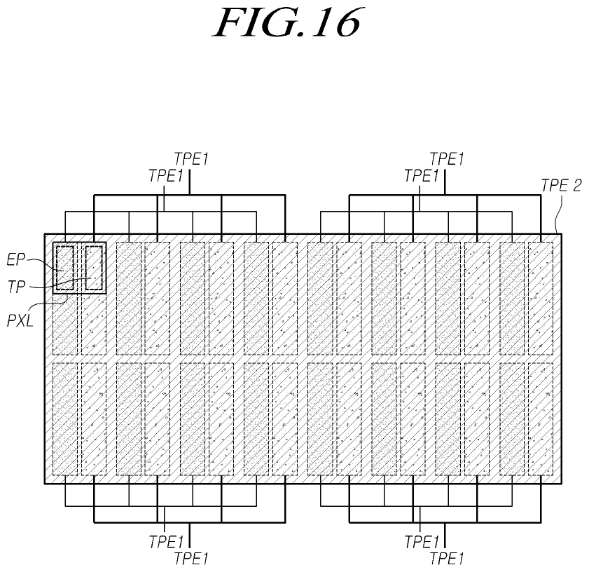

FIG. 16 is a plan view illustrating a display device according to embodiments of the disclosure. More specifically, FIG. 16 can be a plan view of the display device according to the embodiments illustrated in FIGS. 13 and 14.

Referring to FIG. 16, the first transparent electrode TPE1 can be patterned to correspond to areas into which the display area is divided. In other words, like the display device illustrated in FIG. 15, the first transparent electrode TPE1 may not only be patterned to correspond to the light emitting portion EP and the transparent portion TP, but can also be patterned to correspond to any area into which the display area is divided. When the first transparent electrode TPE1 is patterned to correspond to the divided areas of the display area, the switching portion SW can be split driven (e.g., selectively or independently driven) in each of the divided areas, and thus the operation mode of the display device can be more precisely or selectively controlled.

Embodiments of the disclosure described above are briefly described below.

A display device 100 according to embodiments of the disclosure can comprise a light emitting portion EP, a transparent portion TP, and a switching portion SW. The light emitting portion EP can be positioned in a display area DA. The light emitting portion EP can include a light emitting element ED. The transparent portion TP can be positioned in the display area DA. The switching portion SW can be positioned on the light emitting portion EP and the transparent portion TP. The switching portion SW can include a first transparent electrode TPE1, a liquid crystal layer LCL positioned on the first transparent electrode TPE1, and a second transparent electrode TPE2 positioned on the liquid crystal layer LCL.

The liquid crystal layer LCL can include a cholesteric liquid crystal CLC.

The cholesteric liquid crystal CLC can be vertically oriented when a voltage is applied to the first transparent electrode TPE1 and the second transparent electrode TPE2, and can be cholesterically oriented when no voltage is not applied to the first transparent electrode TPE1 and the second transparent electrode TPE2.

The first transparent electrode TPE1 and the second transparent electrode TPE2 can be positioned in the entire display area.

The first transparent electrode TPE1 can be patterned to correspond to the light emitting portion EP and the transparent portion TP.

The light emitting element ED can include an anode electrode AE, a light emitting layer EL positioned on the anode electrode AE, and a cathode electrode CE positioned on the light emitting layer EL. The anode electrode AE and the cathode electrode CE may not be positioned on the transparent portion TP, and the light emitting layer EL can be positioned on the transparent portion TP.

The display device 100 can further comprise a driving transistor DT for driving the light emitting element ED. The driving transistor DT can be positioned not to overlap the transparent portion TP.

The display device 100 can comprise a light shield LS positioned under the driving transistor DT. The light shield LS can be positioned not to overlap the transparent portion TP.

The display device 100 can comprise a first substrate SUB1 on which the light emitting element ED is positioned, a second substrate SUB2 on which the liquid crystal layer LCL is positioned, and an adhesive layer OCA positioned between the first substrate SUB1 and the second substrate SUB2.

The first transparent electrode TPE1 can be electrically connected to a first power source, and the second transparent electrode TPE2 can be electrically connected to a second power source.

The first transparent electrode TPE1 can include a portion corresponding to the light emitting portion EP and a portion corresponding to the transparent portion TP. The portion corresponding to the light emitting portion EP and the portion corresponding to the transparent portion TP can be positioned to be spaced apart from each other.

The portion corresponding to the light emitting portion EP can be electrically connected to the first power source. The portion corresponding to the transparent portion TP can be electrically connected to the second power source. The second transparent electrode TPE2 is positioned in the entire display area and can be electrically connected to the third power source.

The first transparent electrode TPE1 can be patterned to correspond to areas into which the display area DA is divided.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. For example, the disclosed embodiments are intended to illustrate the scope of the technical idea of the disclosure.

What is claimed:

1. A display device, comprising:
a light emitting portion positioned in a display area and including a light emitting element;
a transparent portion positioned in the display area; and
a switching portion positioned on the light emitting portion and the transparent portion, the switching portion including a first transparent electrode, a liquid crystal layer positioned on the first transparent electrode, and a second transparent electrode positioned on the liquid crystal layer.

2. The display device of claim 1, wherein the liquid crystal layer includes a cholesteric liquid crystal.

3. The display device of claim 2, wherein the cholesteric liquid crystal is vertically oriented when a voltage is applied to the first transparent electrode and the second transparent electrode, and
the cholesteric liquid crystal is cholesterically oriented when no voltage is applied to the first transparent electrode and the second transparent electrode.

4. The display device of claim 1, wherein the first transparent electrode and the second transparent electrode are positioned in the entire display area.

5. The display device of claim 1, wherein the first transparent electrode is patterned to correspond to the light emitting portion and the transparent portion.

6. The display device of claim 1, wherein the light emitting element includes an anode electrode, a light emitting layer positioned on the anode electrode, and a cathode electrode positioned on the light emitting layer,
wherein the anode electrode and the cathode electrode are not positioned on the transparent portion, and
wherein the light emitting layer is positioned on the transparent portion.

7. The display device of claim 1, further comprising a driving transistor configured to drive the light emitting element,
wherein the driving transistor is positioned not to overlap the transparent portion.

8. The display device of claim 7, further comprising a light shield positioned under the driving transistor,
wherein the light shield is positioned not to overlap the transparent portion.

9. The display device of claim 1, further comprising:
a first substrate on which the light emitting element is positioned;
a second substrate on which the liquid crystal layer is positioned; and
an adhesive layer positioned between the first substrate and the second substrate.

10. The display device of claim 4, wherein the first transparent electrode is electrically connected to a first power source, and the second transparent electrode is electrically connected to a second power source.

11. The display device of claim 5, wherein the first transparent electrode includes a portion corresponding to the light emitting portion and a portion corresponding to the transparent portion, and
wherein the portion corresponding to the light emitting portion and the portion corresponding to the transparent portion are positioned to be spaced apart from each other.

12. The display device of claim 11, wherein the portion corresponding to the light emitting portion is electrically connected to a first power source, the portion corresponding to the transparent portion is electrically connected to a second power source, and the second transparent electrode is positioned in the entire display area and is electrically connected to a third power source.

13. The display device of claim 11, wherein the first transparent electrode is patterned to correspond to areas into which the display area is divided.

14. The display device of claim 1, further comprising:
a first substrate on which the light emitting element is positioned;
a second substrate on which the liquid crystal layer is positioned; and
a third substrate positioned on the second transparent electrode.
